(19) United States
(12) Patent Application Publication
(10) Pub. No.: US 2023/0386874 A1
(43) Pub. Date: Nov. 30, 2023

(54) SUBSTRATE SUPPORTS, SEMICONDUCTOR PROCESSING SYSTEMS, AND MATERIAL LAYER DEPOSITION METHODS

(71) Applicant: ASM IP Holding, B.V., Almere (NL)

(72) Inventors: Shujin Huang, Tempe, AZ (US); Junwei Su, Tempe, AZ (US); Wentao Wang, Chandler, AZ (US); Xing Lin, Chandler, AZ (US)

(21) Appl. No.: 18/324,411

(22) Filed: May 26, 2023

Related U.S. Application Data
(60) Provisional application No. 63/347,313, filed on May 31, 2022.

(51) Int. Cl. H01L 21/673; H01L 21/687; H01L 21/02; H01L 21/3213

(52) U.S. Cl. CPC H01L 21/67316; H01L 21/68742; H01L 21/02293; H01L 21/3213

(57) ABSTRACT

A substrate support includes a disc body with upper and lower surfaces spaced apart by a thickness. The upper surface has a circular concavity extending about a rotation axis, an annular ledge portion radially outward of the concavity extending circumferentially about the concavity, and an annular rim portion radially outward of the ledge portion extending circumferentially about the ledge portion. The concavity has a circular perforated portion and an annular unperforated portion. The perforated portion extends about the rotation axis and defines two or more perforations to issue an etchant into a cavity defined between the concavity and a backside of a substrate seated on the substrate support. The unperforated portion is radially outward of the perforated portion and extends circumferentially about the perforated portion to limit etching of the backside of the substrate by the etchant. Semiconductor processing systems and material layer deposition methods are also described.

### FIELD OF INVENTION

The present disclosure generally relates to fabricating semiconductor devices. More particularly, the present disclosure relates to supporting substrates in semiconductor processing systems during the deposition of material layers onto substrates during the fabrication of semiconductor devices.

### BACKGROUND OF THE DISCLOSURE

Semiconductor devices, such as integrated circuits and power electronic semiconductor devices, are commonly formed by depositing material layers onto substrates. Material layer deposition is generally accomplished by loading a substrate into a reaction chamber, heating the substrate, and providing a material layer precursor to the reaction chamber. The reaction chamber typically flows the material layer precursor across the substrate under conditions selected to cause a material layer to deposit onto the substrate. Once the material layer reaches a desired thickness, flow of material layer precursor to the reaction chamber ceases, and the substrate is unloaded from the reaction chamber such that the substrate may undergo further processing.

In some deposition operations, accretions may develop within the reaction chamber during the deposition of the material layer on the substrate. For example, the material layer precursor provided to the reaction chamber and/or reaction products may cause accretions to develop on interior surfaces of the reaction chamber walls. The material layer precursor may cause accretions to develop on structures located within the reaction chamber, such as within clearances between structures that are movable relative to one another. And the material layer precursor provided to the reaction chamber may cause accretions to develop between the substrate and the substrate support structure seating the substrate during the deposition process. While generally manageable, accretions on interior surfaces of the reaction chamber walls can complicate temperature control within the reaction chamber, for example, by changing the transmissivity of the reaction chamber walls. Accretions formed within mechanical clearances can reduce reliability by impairing movement of structures, potentially increasing resistance to movement and/or binding. And accretions between the substrate and the substrate support can mechanically fix the substrate to the substrate support, potentially causing damage to reaction chamber components and/or to the substrate itself during unloading subsequent to deposition of the material layer onto the substrate.

Various countermeasures exist to limit the development of accretions within reaction chambers. For example, flow of the material layer precursor may be adjusted to limit accretion development on interior surfaces and structures. A purge gas may be provided to the interior of the reaction chamber to separate the material layer precursor and/or reaction products from interior surfaces and structures. And an etchant may be provided to reaction chamber to etch surfaces and structures prone to accretion development. However, flow pattern adjustments are generally reserved to control material layer thickness profile, purge efficacy may be limited by the tendency of material layer precursor and/or reaction products to diffuse into the purge gas, and etchants may cause damage to the reaction chamber and/or the substrate.

Such systems and methods have generally satisfactory for their intended purpose. However, there remains a need in the art for improved substrate supports, semiconductor processing systems, and methods of depositing material layers onto substrates. The present disclosure provides a solution to this need.

### SUMMARY OF THE DISCLOSURE

A substrate support is provided. The substrate support incudes a disc body arranged along a rotation axis with an upper surface and a lower surface axially offset by a thickness of the disc body. The upper surface of the disc body has a circular concavity, an annular ledge portion, and an annular rim portion. The circular concavity extends about the rotation axis. The annular ledge portion is radially outward of the concavity and extends circumferentially about the concavity. The annular rim portion is radially outward of the ledge portion and extends circumferentially about the ledge portion. The concavity has a circular perforated portion and an annular unperforated portion. The circular perforated portion extends and has a plurality of perforations to issue an etchant into a cavity defined between the upper surface of the substrate support and a backside of a substrate seated on the substrate support. The unperforated portion is radially outward of the perforated portion and extends circumferentially about the perforated portion to axially space the etchant issued into the cavity from the backside of the substrate.

In addition to one or more of the features described above, or as an alternative, a ratio of an unperforated portion radial width to a perforated portion diameter may be between about 1:10 and about 1:1, or between about 3:10 and about 1:1, or even between about 5:1 and about 1:1.

In addition to one or more of the features described above, or as an alternative, further examples of the substrate support may include that the plurality of perforations extend through the thickness of the disc body. The plurality of perforations may fluidly couple the lower surface of the disc body to the upper surface of the disc body.

In addition to one or more of the features described above, or as an alternative, further examples of the substrate support may include that the concavity defines one or more lift pin aperture. The one or more lift pin aperture may extend through the thickness of the disc body. The one or more lift pin aperture may fluidly couple the lower surface of the disc body to the upper surface of the disc body.

In addition to one or more of the features described above, or as an alternative, further examples of the substrate support may include that the one or more lift pin aperture is defined within the perforated portion of the concavity. One or more of the plurality of perforations may separate the one or more lift pin aperture from the unperforated portion of the concavity.

In addition to one or more of the features described above, or as an alternative, further examples of the substrate support may include that the one or more lift pin aperture is defined within the unperforated portion of the concavity. In such examples none of the two or more perforations may radially separate the one or more lift pin aperture from the ledge portion of the upper surface of the disc body.

In addition to one or more of the features described above, or as an alternative, further examples of the substrate support may include that the lower surface of the disc body defines therein one or more elongated slot. The one or more elongated slot may extend radially within the lower surface of the disc body relative to the rotation axis.

In addition to one or more of the features described above, or as an alternative, further examples of the substrate support may include that the unperforated portion of the concavity axially overlays the one or more elongated slot. The one or more elongated slot may be radially aligned with the one or more lift pin aperture.

In addition to one or more of the features described above, or as an alternative, further examples of the substrate support may include that the rim portion of the upper surface of the disc body overlays the one or more elongated slot. The one or more elongated slot may be circumferentially offset from the one or more lift pin aperture.

In addition to one or more of the features described above, or as an alternative, further examples of the substrate support may include that the ledge portion of the upper surface of the disc body defines a substrate seat. The substrate seat may extend circumferentially about the concavity. The substrate seat may extend continuously or discontinuously about the concavity.

In addition to one or more of the features described above, or as an alternative, further examples of the substrate support may include that the ledge portion of the upper surface of the disc body defines a negative ledge angle radially outward of the substrate seat. The ledge portion may slope downward and toward the lower surface of the disc body at the negative ledge angle radially outward of the substrate seat.

In addition to one or more of the features described above, or as an alternative, further examples of the substrate support may include that the ledge portion of the upper surface defines a positive ledge angle radially outward of the substrate seat. The ledge portion may slope upwards and away from the lower surface of the disc body radially outward of the substrate seat.

In addition to one or more of the features described above, or as an alternative, further examples of the substrate support may include that the disc body is defined by a bulk graphite material. The bulk graphite material may be encapsulated by a coating. The coating may be a silicon carbide coating.

A semiconductor processing system is provided. The semiconductor processing system includes a chamber body, a divider, and a substrate support as described above. The chamber body has a hollow interior. The divider is fixed within the interior of the chamber body and divides the interior of the chamber body into an upper chamber and a lower chamber. The divider has a divider aperture extending therethrough fluidly coupling the lower chamber to the upper chamber. The substrate support is arranged within the divider aperture and is supported therein for rotation about the rotation axis. The concavity has one or more lift pin aperture that extends through the thickness of the disc body and which fluidly couples the lower surface of the disc body to the upper surface of the disc body. The lower surface of the disc body has one or more elongated slot defined therein, the one or more elongated slot extending radially relative to the rotation axis.

In addition to one or more of the features described above, or as an alternative, further examples may include that the one or more lift pin aperture is defined within the perforated portion of the concavity. Two or more perforations may radially separate the one or more lift pin aperture from the unperforated portion of the concavity. The rim portion of the upper surface of the disc body may overlay the one or more elongated slot. The one or more elongated slot may be radially aligned with the one or more lift pin aperture.

In addition to one or more of the features described above, or as an alternative, further examples may include that the one or more lift pin aperture is defined within the unperforated portion. The perforations may be radially inward of the one or more lift pin aperture such that none of the perforations radially separating the one or more lift pin aperture from the ledge portion. The unperforated portion may axially overlay the one or more elongated slot. The one or more elongated slot may be circumferentially offset from the one or more lift pin aperture.

In addition to one or more of the features described above, or as an alternative, further examples of the semiconductor processing system may include that the ledge portion of the upper surface defines a substrate seat. The substrate seat may be extending circumferentially about concavity. The ledge portion of the upper surface of the disc body may define a negative ledge angle radially outward of the substrate seat, the ledge portion sloping downward toward the lower surface of the disc body at the negative ledge angle radially outward of the substrate seat.

In addition to one or more of the features described above, or as an alternative, further examples of the semiconductor processing system may include that the ledge portion defines a positive ledge angle radially outward of the substrate seat. The ledge portion may slope upwards and away from the lower surface of the disc body at the positive ledge angle radially outward of the substrate seat in such examples.

In addition to one or more of the features described above, or as an alternative, further examples of the semiconductor processing system may include an injection flange, one or more precursor source (e.g., a first precursor source), and a etchant source. The injection flange may be connected the chamber body. The one or more precursor source may be fluidly coupled to the upper chamber of the chamber body by the injection flange and therethrough to the lower chamber by the divider aperture, and may include a silicon-containing precursor, and an etchant source. The etchant source may be fluidly coupled to the lower chamber of the chamber body by the injection flange and therethrough to the upper chamber by the plurality of perforations extending through the thickness of the disc body, and may include an etchant. The etchant may include hydrochloric acid (HCl).

A material layer deposition method is provided. The method includes, at a substrate support as described above, seating the substrate on the ledge portion of the upper surface of the disc body. A material layer precursor is flows across a top surface of the substrate and a material layer deposited onto the top surface of the substrate using the material layer precursor. As the material layer is deposited onto the top surface of the substrate an etchant is flowed through the perforations of the perforated portion of the concavity and into a cavity defined between backside of the substrate and the concavity to limit the formation of accretions in the cavity. Etching of the backside of the substrate by the etchant is limited by the unperforated portion of the concavity.

In addition to one or more of the features described above, or as an alternative, further examples may include that seating the substrate includes translating a lift pin through the substrate support between an extended position and a retracted position to seat the substrate on the ledge portion of the disc body.

In addition to one or more of the features described above, or as an alternative, further examples of the method may be include etching a stem portion of the lift pin dangling from the disc body with the etchant while the substrate is seated on the substrate support.

In addition to one or more of the features described herein, or as an alternative, further examples of the method may include etching a tip portion of the lift pin received in the upper surface of the disc body while the substrate is seated on the substrate support.

In addition to one or more of the features described above, or as an alternative, further examples of the method may include unseating the substrate by translating the lift pin through the substrate support between the retracted position and the extended position after deposition of the material layer onto the top surface of the substrate.

In addition to one or more of the features described above, or as an alternative, depositing the material layer may include heating the substrate to a material layer deposition temperature that is between about 500 degrees Celsius and about 1200 degrees Celsius, or between about 700 degrees Celsius and about 1200 degrees Celsius, or between about 900 degrees Celsius and about 1200 degrees Celsius.

In additional to one or more of the features described above, or as an alternative, depositing the material layer may include pressurizing an interior of a chamber body housing the substrate support to a deposition pressure that is between about 1 torr and about 760 torr, or between about 20 torr and about 760 torr, or between about 50 torr and about 760 torr.

In addition to one or more of the features described above, or as an alternative, further examples of the method may include that seating the substrate on the substrate support may include cantilevering a radially outer portion of the substrate over the ledge portion of the upper surface of the disc body. The radially outer portion of the substrate may have a radial width between about 1 millimeter and about 25 millimeters, or between about 1 millimeter and about 20 millimeters, or between about 1 millimeter and about 10 millimeters.

In addition to one or more of the features described above, or as an alternative, further examples of the method may include that seating the substrate includes abutting a radially outer edge of the substrate against the ledge portion of the upper surface of the disc body. Abutting the radially outer edge of the substrate against the ledge portion may include abutting a bevel against the ledge portion of the top surface of the substrate.

In addition to one or more of the features described above, or as an alternative, further examples of the method may include that seating the substrate on the substrate support includes translating the lift pin through the perforated portion of the concavity.

In addition to one or more of the features described above, or as an alternative, further examples of the method may include that seating the substrate on the substrate support includes translating the lift pin through the unperforated portion of the concavity.

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a schematic view of a semiconductor processing system including a substrate support in accordance with the present disclosure, showing a substrate seated on the substrate during deposition of a material layer onto an top surface of the substrate;

FIG. 2 is a schematic view of the semiconductor processing system of FIG. 1, showing a gas delivery arrangement providing a material layer precursor and an etchant to the chamber arrangement during deposition of the material layer onto the substrate;

FIG. 3 is a schematic view of the semiconductor processing system of FIG. 1, showing the substrate support supported for rotation about a rotation axis within the chamber arrangement and seating thereon the substrate;

FIG. 4 is a cross-sectional side view of the substrate support of FIG. 1, schematically showing lift pins slidably received within the substrate support and operably associated with a lift pin actuator for seating and unseating substrates from the substrate support;

FIGS. 5-8 are cross-sectional side views of the substrate support of FIG. 4, schematically showing cooperation of the lift pins and a lift pin actuator to seat and unseat a substrate from the substrate support before and after deposition of a material layer onto a top surface of the substrate;

FIG. 9 is a cross-sectional side view of the substrate support of FIG. 1 according to a first example of the present disclosure, showing a disc body having concavity on its upper surface with a radially inner perforated portion and a radially outer unperforated portion;

FIG. 10 is a plan view of the upper surface of the substrate support of FIG. 9, schematically showing lift pin apertures defined in the upper surface of the substrate support at locations radially outward of the perforated portion of the concavity;

FIG. 11 is a plan view the lower surface of the substrate support of FIG. 9 according to the example, schematically showing the lift pin apertures and elongated slots defined in the lower surface at locations radially inward of the lift pin apertures;

FIG. 12 is a cross-sectional side view of the substrate support of FIG. 1 according to another example of the present disclosure, schematically showing a concavity with a perforated portion and an unperforated portion according to example of the present disclosure;

FIG. 13 is a plan view of the upper surface of the substrate support of FIG. 12, schematically showing lift pin apertures defined within the perforated portion of the concavity and radially separated from the unperforated portion by perforations defined within the perforated portion of the concavity;

FIG. 14 is a plan view the lower surface of the substrate support of FIG. 12, schematically showing the lift pin apertures and elongated slots defined in the lower surface of the substrate support at locations radially outward of the unperforated portion of the concavity; and

FIG. 15 is a block diagram of a material layer deposition method in accordance with the present disclosure, showing operations of the method according to an illustrative and non-limiting example of the method.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

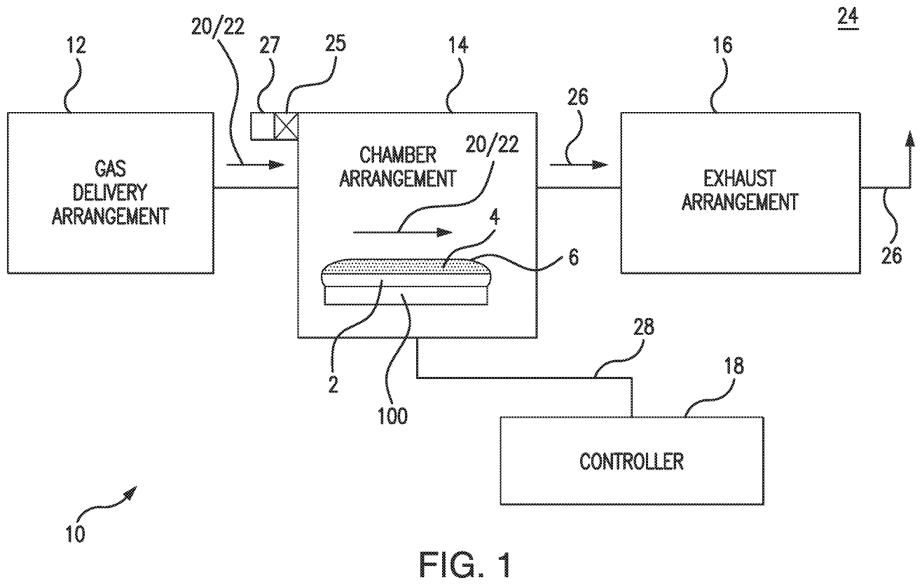

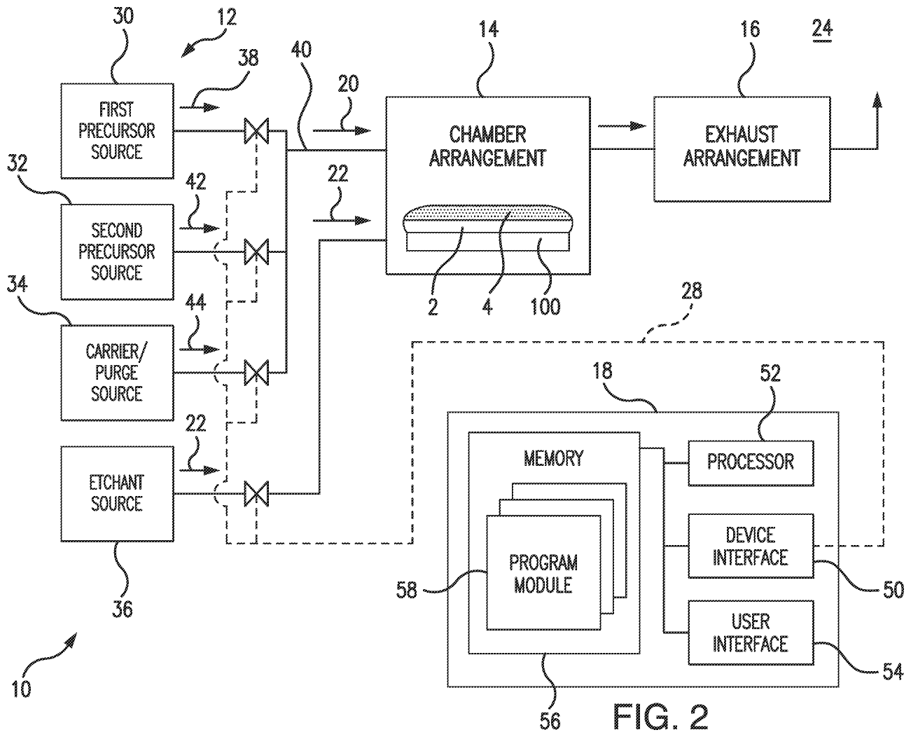

Reference will now be made to the drawings wherein like reference numerals identify similar structural features or aspects of the subject disclosure. For purposes of explanation and illustration, and not limitation, a partial view of an example of a substrate support (e.g., a susceptor) in accordance with the present disclosure is shown in FIG. 1 and is designated generally by reference character 100. Other examples of substrate supports, semiconductor processing systems, and material layer deposition methods in accordance with the present disclosure, or aspects thereof, are provided in FIGS. 2-15, as will be described. The systems and methods of the present disclosure may be used for depositing material layers onto substrates during the fabrication of semiconductor devices, such as during the deposition of thick epitaxial films onto substrates to fabricate power electronic devices, through the present disclosure is not limited to the fabrication of power electronic devices or to the deposition of any particular type of material layer in general.

Referring to FIG. 1, a semiconductor processing system 10 is shown. The semiconductor processing system 10 includes a gas delivery arrangement 12 and a chamber arrangement 14 including the substrate support 100. The semiconductor processing system 10 also includes an exhaust arrangement 16 and a controller 18. Although a particular arrangement of the semiconductor processing system 10 is shown and described herein, it is to be understood and appreciated that semiconductor processing systems having other arrangements can also benefit from the present disclosure.

The gas delivery arrangement 12 is connected to the chamber arrangement 14 and is configured to provide a material layer precursor 20 and an etchant 22 to the chamber arrangement 14. The chamber arrangement 14 houses the substrate support 100, fluidly couples the substrate support 100 to the gas delivery arrangement 12 to receive the material layer precursor and the etchant 22 from the gas delivery arrangement 12, and is configured to provide the material layer precursor 20 and the etchant 22 to the top surface 6 and the backside 8 of the substrate 2, respectively. The exhaust arrangement 16 is connected to the chamber arrangement 14, is fluidly coupled to the substrate support 100, and is configured to communicate a flow of residual material layer precursor and/or reaction products 26 issued by the chamber arrangement 14 to an external environment 24 outside of the semiconductor processing system 10. The controller 18 is operatively connected to the semiconductor processing system 10 and is configured to control deposition of the material layer 4 onto the top surface 6 of the substrate 2. In certain examples, the material layer 4 may be an epitaxial material layer. The material layer 4 may include (e.g., consist of or consist essentially of) silicon. The material layer 4 may be a thick epitaxial layer. The material layer 4 may have a thickness that is between about 40 microns and about 100 microns, or between about 60 microns and about 100 microns, or even between about 80 microns and about 100 microns.

As used herein, a “substrate” refers to any material having a surface onto which material can be deposited. A substrate may include a bulk material, such as semiconductor material like silicon (e.g., single crystal silicon). A substrate may include a wafer, such as 300-millimeter wafer, and may be formed from a semiconductor material such as silicon. A substrate may include one or more layers overlaying the bulk material. The one or more layers overlaying the bulk material may include a pattern including various topologies such as trenches, vias, lines, and the like formed within or on the material layer.

With reference to FIG. 2, the gas delivery arrangement 12 is shown. The gas delivery arrangement 12 includes a first precursor source 30, a second precursor source 32, and carrier/purge gas source 34, and an etchant source 36. The first precursor source 30 is coupled to the chamber arrangement 14 by a precursor conduit 40 and is configured to provide a first precursor 38 to the chamber arrangement 14. In certain examples, the first precursor source 30 may be further coupled to the chamber arrangement 14 by a first precursor valve. The first precursor valve may include a manual actuator, a pneumatic actuator, or an electrical actuator such a solenoid. The first precursor valve may be operatively associated with a controller, such as the controller 18. The first precursor valve may be incorporated in a flow control device, such as a first precursor mass flow controller (MFC) device. In accordance with certain examples, the first precursor 38 may include a silicon-containing precursor. Non-limiting examples of suitable silicon-containing precursor include silane (SiH₄), dichlorosilane (H₂SiCl₂), and trichlorosilane (HCl₃Si).

The second precursor source 32 is coupled to the chamber arrangement 14 by the precursor conduit 40 and is configured to provide a second precursor 42 to the chamber arrangement 14. In certain examples, the second precursor source 32 may be further coupled to the chamber arrangement 14 by a second precursor valve. The second precursor valve may include a manual actuator, a pneumatic actuator, or an electrical actuator. The second precursor valve may be operatively associated with a controller, such as the controller 18. The second precursor valve may be incorporated in a flow control device, such as a second precursor MFC device. In accordance with certain examples, the second precursor 42 may include a dopant or alloying constituent. Non-limiting examples of suitable dopant or alloying constituents include germanium (Ge), arsenic (As), phosphorous (P), and/or boron (B).

The carrier/purge gas source 34 is connected to the chamber arrangement 14 by the precursor conduit 40 and is configured to provide a carrier/purge gas 44 to the chamber arrangement 14. In certain examples, the carrier/purge gas source 34 may be coupled to the chamber arrangement 14 by a carrier/purge gas valve. The carrier/purge gas valve may include a manual actuator, an electrical actuator, or a pneumatic actuator. The carrier/purge gas valve may be operatively associated with a controller, such as the controller 18. The carrier/purge gas valve may be incorporated in a flow control device, such as a carrier/purge gas MFC device. In accordance with certain examples, the carrier/purge gas 44 may include hydrogen (H 2) gas. It is also contemplated that the carrier/purge gas 44 may include an inert gas. Non-limiting examples of suitable inert gases include nitrogen (N 2) gas, argon (Ar) gas, helium (He) gas, mixtures thereof.

The etchant source 36 is connected to the chamber arrangement 14 by an etchant conduit 46 and is configured to provide an etchant 48 to the chamber arrangement 14. In certain examples, the etchant source 36 may be coupled to the chamber arrangement 14 by an etchant gas valve. The etchant valve may include a manual actuator, an electrical actuator, or a pneumatic actuator. The etchant valve may be operatively associated with a controller, such as the controller 18. The etchant valve may be incorporated in a flow control device, such as an etchant MFC device. In accordance with certain examples, the etchant source 36 may further be connected to the chamber arrangement 14 by the precursor conduit 40. In such examples the etchant valve may be a first etchant valve and the etchant source 36 may be coupled to the chamber arrangement 14 by a second etchant valve. In accordance with certain examples, the etchant 48 may include a halide such as chlorine (Cl) or fluorine (F). Non-limiting examples of suitable etchants include chlorine (Cl₂) gas, hydrochloric acid (HCl), and fluorine-containing compounds such as nitrogen trifluoride (NF₃).

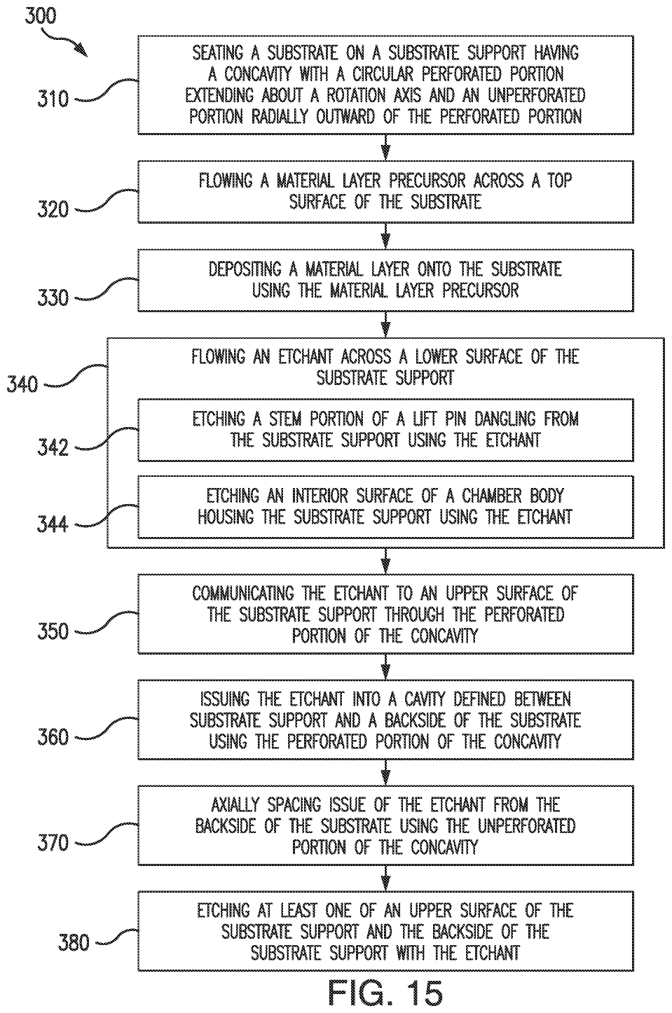

The controller 18 includes a device interface 50, a processor 52, a user interface 54, and a memory 56. The device interface 50 is connected the wired or wireless link 28 and is coupled therethrough to one or more of the gas delivery arrangement 12, the chamber arrangement 14, and the exhaust arrangement 16. The processor 52 is connected to the device interface 50, is operatively connected to the user interface 54 provide and receive therethrough user output and user input and is disposed in communication with the memory 56. The memory 56 includes a non-transitory machine-readable medium. The non-transitory machine-readable medium has a plurality of program modules 58 recorded in the medium that, when read by the processor 52, cause the processor 52 to execute certain operations. Among the operations are operations of a material layer deposition method 300 (shown in FIG. 15), as will be described. Although the gas delivery arrangement 12 and the controller 18 are shown and described herein as having particular arrangements, it is to be understood and appreciated that semiconductor processing systems having gas delivery arrangements and/or controllers with different arrangements may also benefit from the present disclosure.

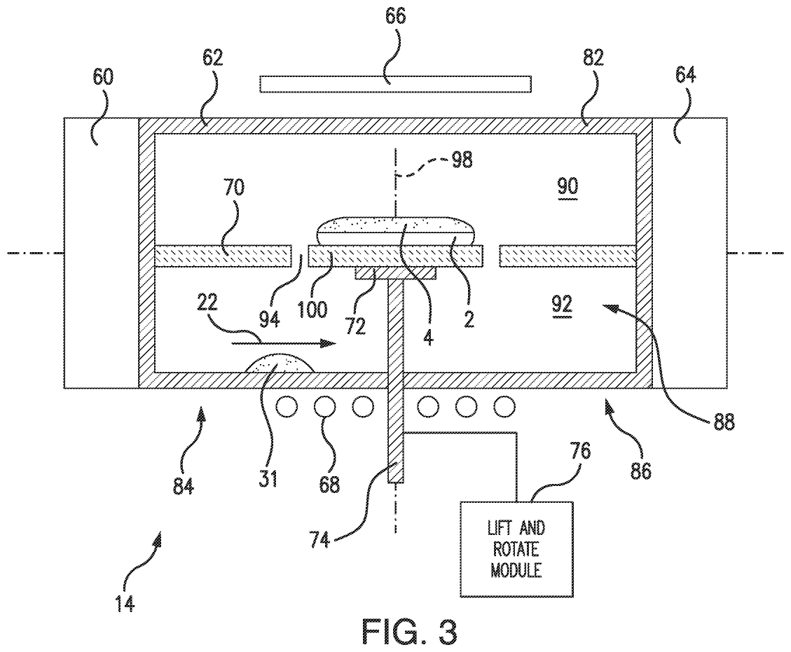

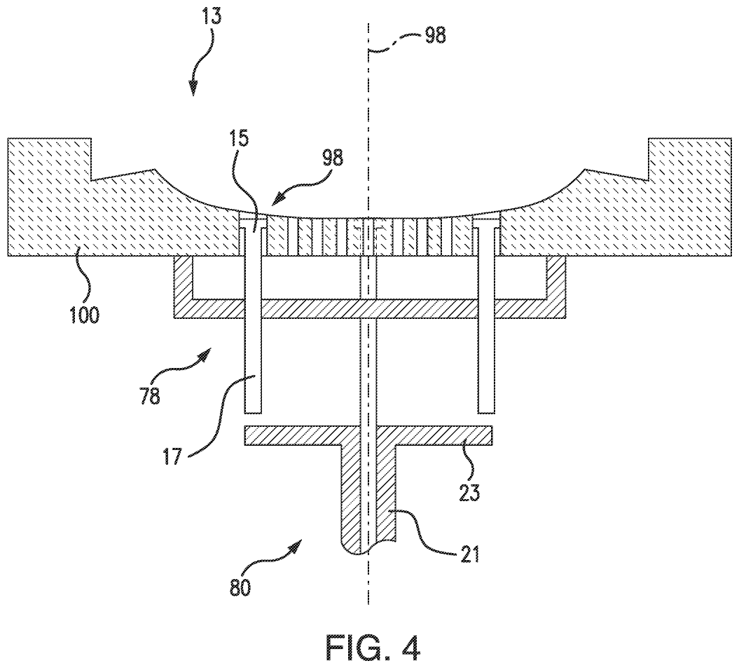

With reference to FIG. 3, the chamber arrangement 14 is shown. The chamber arrangement 14 includes an injection flange 60, a chamber body 62, and an exhaust flange 64. The chamber arrangement 14 also includes an upper lamp array 66, a lower lamp array 68, and a divider 70. The chamber arrangement 14 further includes a support member 72, a shaft member 74, a lift and rotate module 76, one or more lift pin 78 (shown in FIG. 4), and a lift pin actuator 80 (also shown in FIG. 4). Although a particular arrangement of the chamber arrangement 14 is shown and described herein, it is to be understood and appreciated that the chamber arrangements having other arrangement may also benefit from the present disclosure.

The chamber body 62 is formed from a transparent material 82 and has an injection end 84 and a longitudinally opposite (relative to a general direction of fluid flow through the chamber body 62) exhaust end 86. The chamber body 62 also has an interior 88, which is hollow. The injection flange 60 is connected to the injection end 84 of the chamber body 62 and fluidly couples the gas delivery arrangement 12 (shown in FIG. 1) to the interior 88 of the chamber body 62. The exhaust flange 64 is connected to the exhaust end 86 of the chamber body 62 and is fluidly coupled to the interior 88 of the chamber body 62. It is contemplated that the exhaust flange 64 fluidly couple the interior 88 of the chamber body 62, and therethrough the gas delivery arrangement 12, to the exhaust arrangement 16 (shown in FIG. 1). In certain examples, the transparent material 82 forming the chamber body 62 may be ceramic material. Examples of suitable transparent materials include quartz.

The upper lamp array 66 is supported above the chamber body 62 and is configured to heat the substrate 2 while seated on the substrate support 100. In certain examples the upper lamp array 66 may include one or more linear lamp. The upper lamp array 66 may include a filament-type lamp. The upper lamp array 66 may include one or more linear lamp extending longitudinally above the chamber body 62 between the injection end 84 and the exhaust end 86 of the chamber body 62. In accordance with certain examples, the upper lamp array 66 may include a plurality of linear lamps. The plurality of linear lamps may be laterally spaced apart from one another between the longitudinally opposite injection end 84 and the exhaust end 86 of the chamber body 62. The plurality of linear lamps may extend laterally across the chamber body 62 between laterally opposite sides of the chamber body 62.

The lower lamp array 68 is similar to the upper lamp array 66 and is additionally supported below the chamber body 62. In certain examples, the lower lamp array 68 may include one or more linear lamp. The one it more linear lamp may be substantially orthogonal to the one or more linear lamp of the upper lamp array 66. In accordance with certain examples, the lower lamp array 68 may include one or more spot lamp. The one or more spot lamp may be oriented upwards towards the chamber body 62. The one or more spot lamp may be offset from the rotation axis 98 and oblique relative to the rotation axis 98.

The divider 70 is seated within the interior 88 of the chamber body 62 and divides the interior 88 into an upper chamber 90 (relative to gravity) and a lower chamber 92. It is contemplated that the divider 70 have a divider aperture 94. The divider aperture 94 extends through a thickness of the divider 70 and fluidly couples an upper surface of the divider 70 to a lower surface of the divider 70. The divider aperture 94 further couples the upper chamber 90 to the lower chamber 92 of the chamber body 62. In certain examples, the divider 70 may be formed from an opaque material 96. The opaque material 96 may have a transmissivity to electromagnetic radiation within wavelengths emitted by the upper lamp array 66 and/or the lower lamp array 68 that is lower than a transmissivity of the transparent material 82 forming the chamber body 62. Non-limiting examples of suitable opaque materials include graphite and pyrolytic carbon materials. In accordance with certain examples, the divider 70 may be encapsulated (at least partially) with a coating. Non-limiting examples of suitable coatings include ceramic coatings, such silicon carbide (SiC) coatings.

The substrate support 100 is configured to support substrates during the deposition of material layers onto the substrate, e.g., the substrate 2 (shown in FIG. 1) during deposition of the material layer 4 (shown in FIG. 4) onto the substrate 2. In this respect it is contemplated that the substrate support 100 be arranged within the interior 88 of the chamber body 62 and supported for rotation R about a rotation axis 98 relative to the chamber body 62. More specifically, the substrate support 100 is arranged within the divider aperture 95 and is supported within (at least partially) the divider aperture 94 for rotation R about the rotation axis 98 relative to the chamber body 62. It is further contemplated that the substrate support 100 be operably associated with the lift and rotate module 76. In the illustrated example the substrate support 100 is coupled to the lift and rotate module 76 by the support member 72 and the shaft member 74, the support member 72 arranged within the lower chamber 92 and fixed in rotation relative to the substrate support 100, the shaft member 74 fixed in rotation relative to the support member 72 and extending through a lower wall of the chamber body 62 for operable association with the lift and rotate module 76 in the external environment 24. The support member 72 and/or the shaft member 74 may be formed from a transparent material. Examples of suitable transparent materials include quartz. As will be appreciated by those of skill in the art in view of the present disclosure, the substrate support 100 may supported with a different support arrangement in other examples and remain within the scope of the present disclosure.

With reference to FIG. 4, the lift pin 78 and the lift pin actuator 80 are shown. The lift pin 78 is configured for seating and unseating of the substrate 2 from the substrate support 100. In this respect it is contemplated that the lift pin 78 have a tip portion 15 and an opposite stem portion 17. The lift pin 78 is further slidably received in the substrate support 100 and movable between a retracted position 11 and an extended position 13. When in the retracted position 11 the tip portion 15 of the lift pin 78 is captive within the substrate support 100 (or the surface thereof), and the stem portion 17 dangles from the substrate support 100 within the lower chamber 92 of the chamber body 62. When in the extended position 13 the stem portion 17 is slidably received within (at least partially) the substrate support 100, and tip portion 15 is supported above the substrate support 100 in the upper chamber 90 of the chamber body 62. In certain examples, the tip portion 15 of the lift pin 78 may have a protruding portion configured for rendering the lift pin 78 captive in the substrate support 100. In accordance with certain examples, the lift pin 78 may be formed from a ceramic material. Examples of suitable ceramic materials include silicon carbide and glassy carbon. Although shown and described herein as including three (3) lift pins, it is to be understood and appreciate that substrate support 100 may have fewer than three (3) lift pins or more than three (3) lift pins and remain within the scope of the present disclosure.

The lift pin actuator 80 is configured to move the lift pin 78 between the retracted position 11 and the extended position 13. In this respect it contemplate that the lift pin actuator 80 have a tubular portion 21 and a pedestal portion 23. The tubular portion 21 extends through the lower wall of the chamber body 62 and about the shaft member 74, and is disposed (at least partially) within the lower chamber 92 of the chamber body 62. The pedestal portion 23 extends laterally from the tubular portion 21 of the lift pin actuator 80 within the lower chamber 92 of the chamber body 62, and is arranged below the substrate support 100 and the lift pin 78. It is contemplated that the lift pin actuator 80 be operably associated with the lift and rotate module 76 (shown in FIG. 3) for moving the lift pin 78 between the retracted position 11 and the extended position 13. In certain examples, the lift pin actuator 80 may be formed from a ceramic material. Examples of the suitable ceramic materials include quartz. As will be appreciated by those of skill in the art in view of the present disclosure, other lift pin actuator arrangements are possible and remain within the scope of the present disclosure.

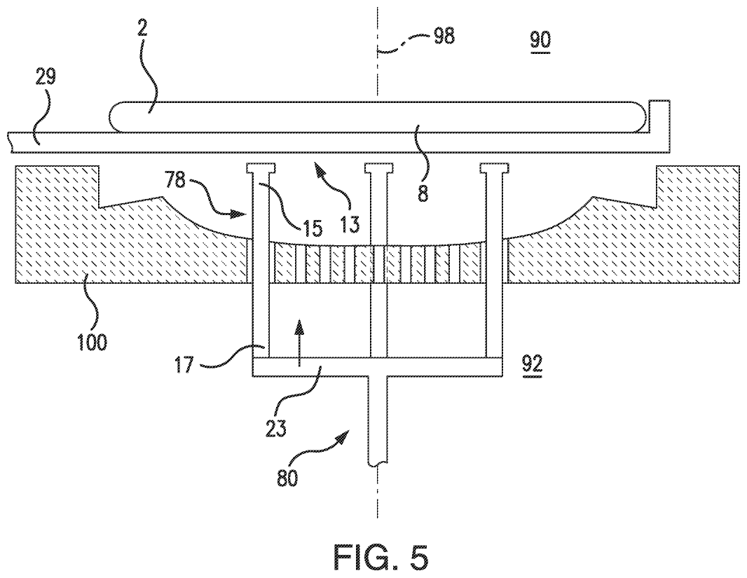

Referring to FIGS. 5-8, seating and unseating of the substrate 2 is shown. As shown in FIG. 5, seating of substrate 2 on the substrate support 100 is accomplished by first loading the substrate 2 into the upper chamber 90 of the chamber body 62 (shown in FIG. 3). In this this respect it is contemplated that a gate valve 25 (shown in FIG. 1) connected to the chamber body 62 be opened. It is further contemplated that opening the gate valve 25 allow a substrate transfer robot 27 (shown in FIG. 1) coupled to the chamber body 62 by the gate valve 25 to advance an end effector 29 carrying the substrate 2 into the upper chamber 90 of the chamber body 62, for example, through a lateral slot defined within the injection flange 60 (shown in FIG. 3). Advancing the end effector 29 into the upper chamber 90 positions the substrate 2 above the substrate support 100 and the lift pin 78, for example, in registration with the substrate support 100.

Next, the lift and rotate module 76 (shown in FIG. 3) rotates the substrate support 100 about the rotation axis 98 such that the lift pin 78 is registered in rotation above the pedestal portion 23 of the lift pin actuator 80. The lift and rotate module 76 then translates the lift pin actuator 80 upwards along the rotation axis 98 relative to the substrate support 100 and toward the one or more lift pin 78. As the lift pin actuator 80 translates along the rotation axis 98 the pedestal portion 23 of the lift pin actuator 80 comes into abutment with the stem portion 17 of the one or more lift pin 78, continuing translation of the lift pin actuator 80 thereafter driving the one or more lift pin 78 upwards within the upper chamber 90 relative to the substrate support 100. As the one or more lift pin 78 is driven upward the tip portion 15 of the one or more lift pin 78 comes into abutment with the backside 8 of the substrate 2, continued upward translation of the one or more lift pin 78 thereafter shifting weight of the substrate 2 to the one or more lift pin 78. It is contemplated that the lift and rotate module 76 continue to translate the lift pin actuator 80 upwards along the rotation axis 98 until the lift pin reaches the extended position 13 such that the substrate 2 is clear of the end effector 29. Shifting the substrate 2 to the lift pin 78 allows the substrate transfer robot 27 (shown in FIG. 1) to withdraw the end effector 29 from the upper chamber 90 and the gate valve 25 to close, the interior 88 (shown in FIG. 3) of the chamber body 62 (shown in FIG. 3) thereby being fluidly isolated from the external environment 24 (shown in FIG. 1).

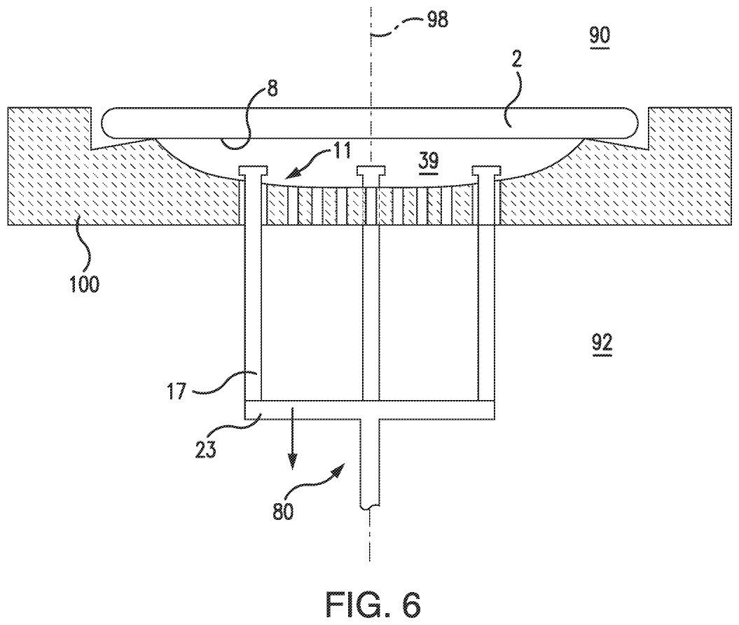

As shown in FIG. 6, seating of the substrate 2 on the substrate support 100 is accomplished by downward translation of the lift pin actuator 80 within the lower chamber 92. In this respect it is contemplated that the lift and rotate module 76 (shown in FIG. 3) translate the lift pin actuator 80 along the rotation axis 98 downward relative to the substrate support 100. Downward translation of the lift pin actuator 80 causes the one or more lift pin 78 to slide downward through the substrate support 100 by operation of gravity in concert with the downward translation of the lift pin actuator 80, the stem portion 17 of the one or more lift pin 78 sliding through the substrate support 100 such that the stem portion 17 of the lift pin 78 remains in abutment with the pedestal portion 23 of the lift pin actuator 80. It is contemplated that downward movement of the substrate 2 ceases when the backside 8 of the substrate 2 comes into abutment with the substrate support 100, support of the substrate 2 transferring from the one or more lift pin 78 to the substrate support 100 as the one or more lift pin 78 further slides downward through the substrate support 100 by operation of gravity as the lift and rotate module 76 continues to translate the lift pin actuator 80 downward along the rotation axis 98 relative to the substrate support 100. Downward movement of the lift pin 78 ceases when the tip portion 15 of the one or more lift pin 78 reaches the retracted position 11 and becomes captive within the substrate support 100. Further downward translation of the lift pin actuator 80 thereafter causes the pedestal portion 23 of the lift pin actuator 80 to separate from the stem portion 17 of the lift pin 78 axially, the stem portion 17 of the one or more lift pin 78 thereafter dangling from the substrate support 100 within the lower chamber 92 of the chamber body 62.

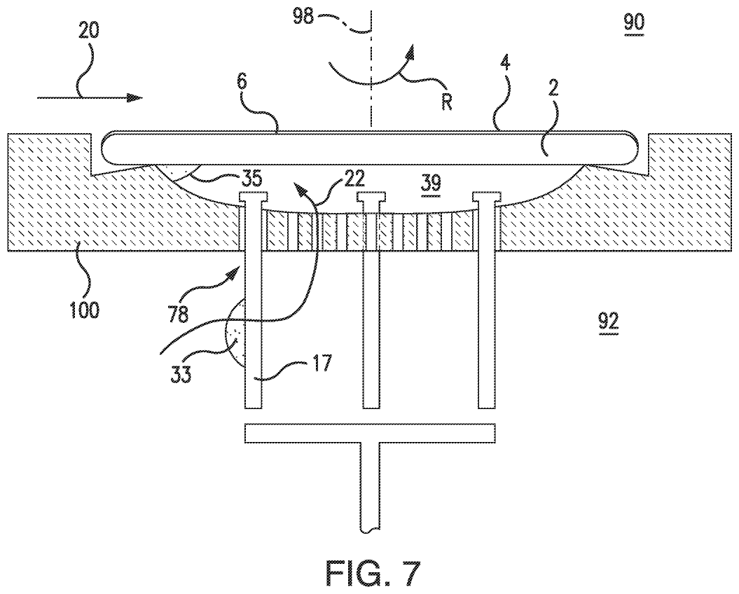

As shown in FIG. 7, material layer deposition on the substrate is accomplished by rotating the substrate support 100 (and the substrate 2) about the rotation axis 98 using the lift and rotate module 76 (shown in FIG. 3), heating the substrate 2 to a predetermined material layer deposition temperature using the upper lamp array 66 (shown in FIG. 3) and the lower lamp array 68 (shown in FIG. 3), and providing the material layer precursor 20 to the chamber arrangement 14 (shown in FIG. 1) using the gas delivery arrangement 12 (shown in FIG. 1). It is contemplated that the chamber body 62 flow the material layer precursor 20 across the top surface 6 of the substrate 2, that thermal and pressure conditions within the upper chamber 90 of the chamber body 62 cause the material layer 4 to deposit onto the top surface 6 of the substrate 2, and that the residual precursor and/or reaction products 26 (shown in FIG. 1) associated with the deposition be communicated to the exhaust arrangement 16 (shown in FIG. 1). Once the material layer 4 reaches a predetermined thickness, flow of the material layer precursor 20 to the chamber arrangement 14 by the gas delivery arrangement 12 ceases, rotation of the substrate support 100 by the lift and rotate module 76 ceases, and heating of the substrate 2 by the upper lamp array 66 and the lower lamp array 68 ceases.

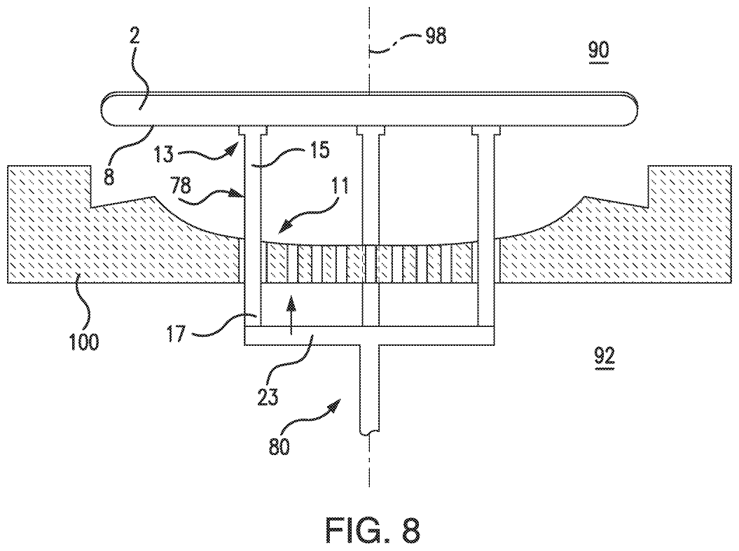

As shown in FIG. 8, unloading of the substrate 2 from the substrate support 100 is accomplished by cooperation of the lift and rotate module 76 (shown in FIG. 3) with the lift pin actuator 80 and the one or more lift pin 78. In this respect it is contemplated that the lift and rotate module 76 first rotate the substrate support 100 such that the lift pin 78 is registered in rotation about the rotation axis 98 relative to the pedestal portion 23 of the lift pin actuator 80. Next, the lift and rotate module 76 translates the lift pin actuator 80 upwards along the rotation axis 98. As the lift pin actuator 80 translates upwards along rotation axis 98 the pedestal portion 23 of the lift pin actuator 80 unseats the one or more lift pin 78 from the substrate support 100, drives the one or more lift pin 78 into abutment with the backside 8 of the substrate 2 such that support of the substrate 2 shifts to the lift pin 78, and thereafter positions the substrate 2 above the substrate support 100 in the upper chamber 90 of the chamber body 62 (shown in FIG. 3). The gate valve (shown in FIG. 1) then opens, the substrate transfer robot 27 (shown in FIG. 1) advances the end effector 29 (shown in FIG. 5) into the upper chamber 90 to a location between the substrate 2 and the substrate support 100. So positioned, the lift and rotate module 76 again translates the lift pin actuator 80 downwards along the rotation axis 98 such that the tip portion 15 of the one or more lift pin 78 once again becomes captive in the substrate support 100, the substrate 2 transferring from the one or more lift pin 78 to the end effector 29 as the one or more lift pin 78 moves from the extended position 13 to the retracted position 11.

With continuing reference to FIG. 7, as has been explained above, accretions may form during the deposition of some types of material layers. For example, with respect to the chamber arrangement 14 (shown in FIG. 1), wall surface accretions such as the wall surface accretion 31 (shown in FIG. 3) may form on interior surfaces of the chamber body 62 (shown in FIG. 3), potentially reducing transmissivity of the transparent material 82 (shown in FIG. 3) forming the chamber body 62 and adding complexity to controlling temperature of the substrate 2. Lift pin accretions such as the lift pin accretion 33 may also (or alternatively) form on the stem portion 17 of the one or more lift pin 78, potentially increasing resistance to lift pin movement and/or causing the one or more lift pin 78 to bind within the substrate support 100. And substrate backside accretions such as a backside accretion 35 may further (or alternatively) form on the backside 8 of the substrate 2, potentially leading to damage to the substrate 2 (in the case of bridging) and/or contamination during subsequent handling of the substrate 2. For that reason it is contemplated that the etchant 22 be provided to the lower chamber 92 of the chamber body 62 during at least a portion of the deposition of the material layer 4 onto the top surface 6 of the substrate 2.

Without being bound by a particular theory or mode of operation, it is believed that providing the etchant 22 limits (or eliminates) the formation of accretions within the chamber body 62 (shown in FIG. 3) by etching surfaces and structures contacted by the etchant 22. For example, it is contemplated that the etchant 22 etch interior surfaces of the chamber body 62, limiting (or eliminating) formation of accretions on the interior surfaces of the chamber body 62 and preventing such accretions from interfering with heating of the substrate 2. It is contemplated that the etchant 22 etch the stem portion 17 of the lift pin 78 as the stem portion 17 dangles within the lower chamber 92 of the chamber body 62, also limiting (or eliminating) accretions formation on the stem portion 17 and reducing (or eliminating) risk that such accretions cause the lift pin 78 to bind within the substrate support 100 during movement between the retracted position 11 and the extended position 13. And it is contemplated that the etchant 22 flow into a cavity 39 defined between the substrate support 100 and the substrate 2, the etchant 22 etching the substrate support 100 and the backside 8 of the substrate 2 to limit (or prevent) accretion formation on the substrate support 100 and/or the backside 8 of the substrate 2.

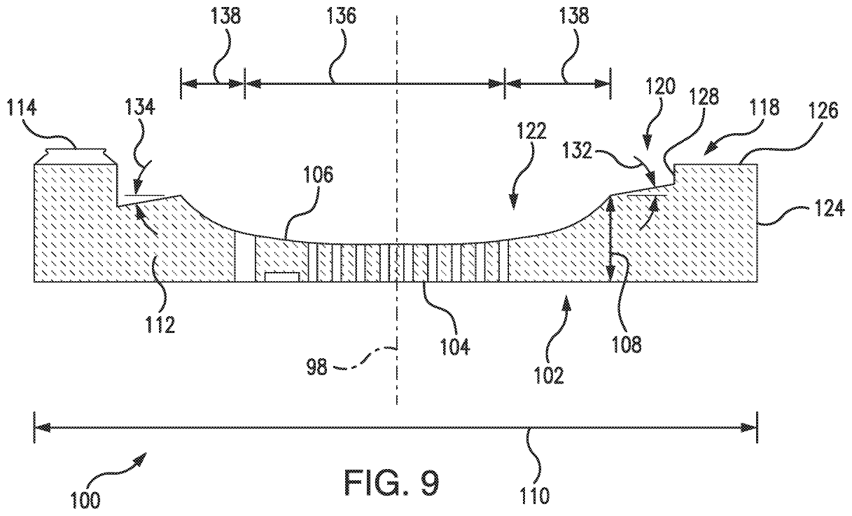

As will also be appreciated by those of skill in the art in view of the present disclosure, issue of the etchant 22 into the cavity 39 may, under certain flow and pressure conditions, cause the etchant to etch the bulk material defining the backside 8 of the substrate 2. While generally manageable, such etching can, in some deposition operations, lead to the creation of backside artifacts on the substrate 2 corresponding to a radially outer circumferential grouping of the perforations 140 defined by the concavity 122. To limit such artifact creation, the substrate support 100 has a concavity 122 (shown in FIG. 9) with an unperforated portion 138 (shown in FIG. 9) located radially outward of a perforated portion 136 (shown in FIG. 9) to limit issue of the etchant into the cavity 39 to portions of the concavity 122 that are axially separated from the substrate 2 by distance sufficient to allow the etchant 22 to diffuse into the atmosphere within the cavity 39, preventing the generation of backside artifacts while retaining the aforementioned accretion formation mitigation or prevention by etching of surfaces and structures located within the interior 88 (shown in FIG. 3) of the chamber body 62 (shown in FIG. 3).

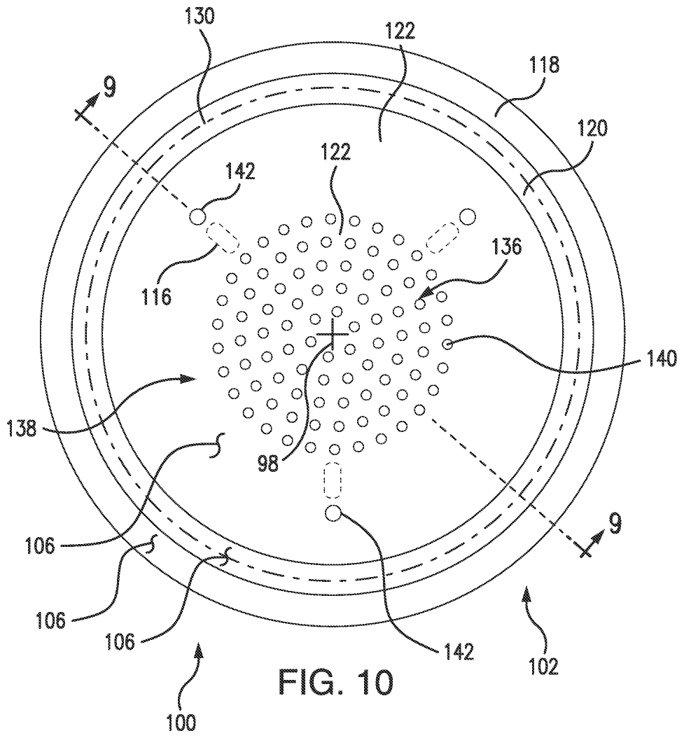

With reference to FIGS. 9-11, the substrate support 100. As shown in FIG. 9, the substrate support 100 includes a disc body 102 with a lower surface 104, an upper surface 106 (shown in FIG. 10) opposite the lower surface 104 and a thickness 108. The lower surface 104 of the disc body 102 is arranged along the rotation axis 98 and extends about the rotation axis 98. The upper surface 106 of the disc body 102 is spaced apart from the lower surface 104 along the rotation axis 98 by the thickness 108 of the disc body 102, extends about the rotation axis 98 and is configured to seat the substrate 2 (shown in FIG. 2). In certain examples, the disc body 102 may have a disc body diameter 110 that is greater than a diameter of the substrate 2. For example, the disc body diameter 110 may be between about 300 millimeters and about 375 millimeters, or between about 350 millimeters and about 375 millimeters, or even between about 370 millimeters and about 375 millimeters. As will be appreciated by those of skill in the art in view of the present disclosure, sizing the disc body diameter 110 to within these ranges allows the substrate support 100 to seat thereon a substrate including a 300-millimeter silicon wafer. As will also be appreciated by those of skill in the art in view of the present disclosure, sizing the disc body diameter 110 to within these ranges can also limit disruption of the precursor flow pattern through the chamber body 62 (shown in FIG. 3) due to structures and/or features that could otherwise disturb the flow pattern, such as gap between the periphery (e.g., bevel) of the substrate 2 and the substrate support 100 and/or between the substrate support 100 and the divider 70 (shown in FIG. 3), by way of non-limiting example.

In certain examples, the disc body 102 may be formed from an opaque material 112. The opaque material 112 may be opaque to electromagnetic radiation within a waveband emitted by one or more of the heat lamps of the upper lamp array 66 (shown in FIG. 3) and/or the lower lamp array 68 (shown in FIG. 3). The opaque material 112 may include (or consist of or consist essentially of) graphite. The opaque material 112 may include (or consist of or consist essentially of) pyrolytic carbine. In accordance with certain examples, the disc body 102 may be encapsulated (at least partially) by a coating 114. The coating 114 may encapsulate the opaque material 112. The coating 114 may include a ceramic material such as silicon carbide (SiC) by way of non-limiting example.

As shown in FIG. 10, the lower surface 104 of the disc body 102 has a circular shape and defines therein one or more elongated slot 116. The one or more elongated slot 116 extends axially into the thickness 108 (shown in FIG. 9) of the disc body 102 and radially relative to the rotation axis 98. It is contemplated that the one or more elongated slot 116 be configured receive therein a finger portion of the support member 72 (shown in FIG. 3), the finger portion extending upwards from the support member 72 along the rotation axis 98, the substrate support 100, the support member 72 thereby being fixed in rotation relative to the support member 72 about the rotation axis 98. It is further contemplated that the finger portion of the support member 72 be radially free relative the substrate support 100, the substrate support 100 and the support member 72 thereby being free to expand at different rates during heating of the substrate 2 (shown in FIG. 1). As will be appreciated by those of skill in the art in view of the present disclosure, this allows the substrate support 100 and the support member 72 to be formed from different materials and avoiding the tendency of the different materials to cause the decentering of the substrate support 100 within the divider aperture 94 during heating of the substrate 2. In the illustrated example the one or more elongated slot 116 defined in the lower surface 104 of the disc body 102 comprises three (3) elongated slots. As will be appreciated by those of skill in the art in view of the present disclosure, the lower surface 104 of the disc body 102 may have fewer or more than three (3) elongated slots and remain within the scope of the present disclosure.

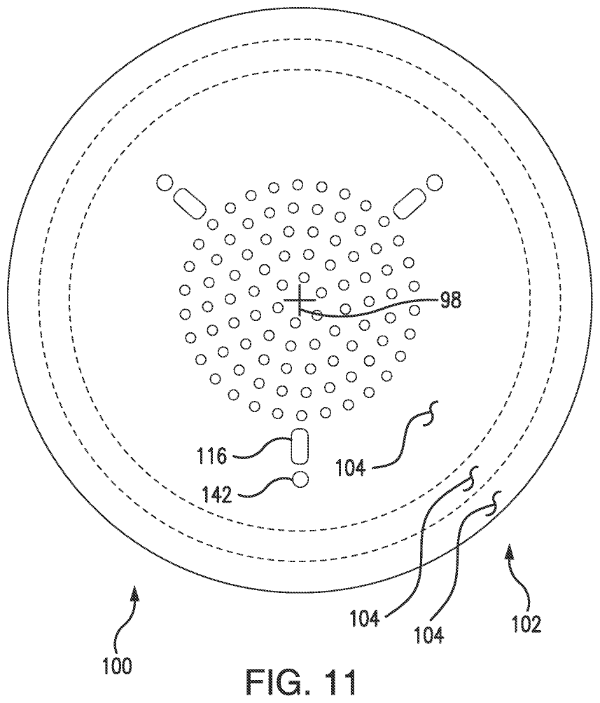

As shown in FIG. 11, the upper surface 106 of the disc body 102 is circular in shape and has a rim portion 118, a ledge portion 120 and a concavity 122. The rim portion 118 of the upper surface 106 is generally annular in shape, is located radially outward of the ledge portion 120 of the upper surface 106 of the disc body 102 and extends circumferentially about the ledge portion 120 of the upper surface 106 of the disc body 102. The rim portion 118 further has an outer periphery 124, a rim surface 126 and an inner periphery 128. The outer periphery 124 of the rim portion 118 spans the lower surface 104 and the upper surface 106 of the disc body 102, extends circumferentially about the rotation axis 98, and is arranged at least partially in the divider aperture 94 (shown in FIG. 3). In this respect the outer periphery 124 opposes the divider 70 (shown in FIG. 3) and is spaced apart from the divider 70 by a circumferential gap extending about the substrate support 100. The rim surface 126 extends radially inward from the outer periphery 124 and circumferentially between the outer periphery 124 and the inner periphery 128 of the rim portion 118. In certain examples, the rim surface 126 may be substantially planar. In accordance with certain examples, the rim surface 126 may be substantially coplanar with the top surface 6 (shown in FIG. 1) of the substrate 2 (show in FIG. 1). It is also contemplated that, in accordance with certain examples, the rim surface 126 may axially offset from the top surface 6 of the substrate 2 or below the top surface 6 of the substrate 2. For example, the rim surface 126 may be on a side of the top surface 6 of the substrate 2 opposite the concavity 122 or between the top surface 6 of the substrate 2 and the concavity 122. As will be appreciated by those of skill in the art in view of the present disclosure, arrangement of the rim surface 126 relative to the top surface 6 of the substrate 2 may be selected according to impart a predetermined thickness profile into the material layer 4 (shown in FIG. 1) deposited onto the top surface 6 of the substrate 2, such as an edge thickness profile, for the material layer 4 supported by the substrate support 100.

The inner periphery 128 of the rim portion 118 extends axially along the rotation axis 98 between the rim surface 126 and the ledge portion 120 and extends about the rotation axis 98. In certain examples, the inner periphery 128 may axially overlap the ledge portion 120. In accordance with certain examples, the inner periphery 128 of the rim portion 118 may be axially offset from the ledge portion 120 along the rotation axis 98. The inner periphery 128 may join the ledge portion 120 at a fillet structure. Alternatively (or additionally), the inner periphery 128 may join the rim surface 126 at a chamfer structure. As will be appreciated by those of skill in the art in view of the present disclosures, employment of a fillet structure between the inner periphery 128 and the ledge portion 120 and/or a chamfer structure between the inner periphery 128 and the rim surface 126 may simplify fabrication of the disc body 102 of the substrate support 100.

Referring to FIGS. 9 and 11, the ledge portion 120 of the upper surface 106 is generally annular in shape and is radially between the rim portion 118 and the concavity 122. The ledge portion 120 further defines a substrate seat 130. The substrate seat 130 extends circumferentially about the concavity 122 and defines a profile that is oblique relative to the rotation axis 98 relative to a plane orthogonal relative to the rotation axis 98. In certain examples the substrate seat 130 may extend continuously about the concavity 122 relative to a plane orthogonal to the rotation axis 98. In accordance with certain examples, the substrate seat 130 may extend discontinuously about rotation axis 98. As will be appreciated by those of skill in the art in view of the present disclosure, substrate seats extending continuously about the rotation axis 98 may limit flow of etchant issued into the cavity 39 (shown in FIG. 6), reducing (or eliminating) the effect that the etchant could otherwise have on the material layer 4 (shown in FIG. 1) deposited onto the top surface 6 (shown in FIG. 1) of the substrate 2 (shown in FIG. 1). As will also be appreciated by those of skill in the art in view of the present disclosure, discontinuously substrate seats can reduce tendency of bridging to develop between the substrate 2 and the substrate support 100, limiting (or eliminating) the tendency of such bridging to cause damage to the material layer 4 and/or the substrate 2.

In certain examples, the ledge portion 120 may slope upwards at a positive ledge angle 132 relative to a plane orthogonal relative to the rotation axis 98. In this respect the ledge portion 120 may slope upwards and in a direction away from the lower surface 104 radially outward of the substrate seat 130, the substrate seat 130 thereby configured to seat thereon a periphery or bevel of the substrate 2 (shown in FIG. 1). As will be appreciated by those of skill in the art in view of the present disclosure, positive ledge angles allow the substrate 2 to be supported at its radially outer periphery, promoting single-direction communication of heat between the substrate 2 and the substrate support 100.

In accordance with certain examples, the ledge portion 120 of the disc body 102 may slope downwards at a negative ledge angle 134 relative to a plane orthogonal to the rotation axis 98. In such examples the ledge portion 120 may slope downwards and in a direction toward the lower surface 104 of the substrate support 100 radially outward of the substrate seat 130. As will be appreciated by those of skill in the art in view of the present disclosure, negative ledge angles allow a radially outer peripheral portion of the substrate 2 (shown in FIG. 1) to be cantilevered over the ledge portion 120 radially outward of the rotation axis 98. For example, a radially outer portion of the substrate 2 having a radial width between about 1 millimeter and about millimeters, or between about 1 millimeter and about 20 millimeters, or even between about 1 millimeter and about 10 millimeters may be cantilevered over the ledge portion 120 radially outward of the substrate seat 130. So cantilevered, the radially outer peripheral portion of the substrate 2 shields the underlying radially outer portion of the ledge portion 120 from flow of material layer precursor 20 (shown in FIG. 1) within the upper chamber 90 (shown in FIG. 3) of the chamber body 62 (shown in FIG. 3), limiting (or eliminating) the tendency of the material layer precursor 20 and/or reaction products from contributing to the development of bridging between the substrate 2 and the substrate support 100 on the ledge portion 120 at locations radially outward of the substrate seat 130.

The concavity 122 is circular in shape and extends about the rotation axis 98. The concavity 122 further has a perforated portion 136 and an unperforated portion 138. The perforated portion 136 of the concavity 122 is generally circular in shape and extends about the rotation axis 98. The perforated portion 136 further defines therein a plurality of perforations 140. The plurality of perforations 140 are configured to issue the etchant 22 (shown in FIG. 1) into the cavity 39 (shown in FIG. 6) and in this respect extend through the thickness 108 of the disc body 102 and fluidly couple the lower surface 104 of the disc body 102 with the upper surface 106 of the disc body 102. In certain examples the plurality of perforations 140 may be distributed circumferentially about the rotation axis 98. In this respect the plurality of perforations 140 may defined on a uniform circumferential pitch relative to the rotation axis 98. The plurality of perforations 140 may further be defined on a uniform radial pitch relative to the rotation axis 98. In accordance with certain examples, the plurality of perforations 140 may be defined on a uniform circumferential pitch and a uniform radial pitch relative to the rotation axis 98, for example, on a radial pitch relative to the rotation axis 98 that is substantially equivalent to a circumferential pitch relative to the rotation axis 98. It is also contemplated that, in accordance with certain examples, the plurality of perforations may be distributed on an nonuniform circumferential and/or radial pitch relative to the rotation axis 98 and remain within the scope of the present disclosure.

The unperforated portion 138 of the disc body 102 is generally annular in shape, is located radially outward of the concavity 122, and extends circumferentially about the perforated portion 136 of the concavity 122. In this respect it is contemplated that the unperforated portion 138 be configured to limit etching of the backside 8 (shown in FIG. 6) of the substrate 2 (shown in FIG. 1) by the etchant 22 (shown in FIG. 1) issue into the cavity 39 defined between the backside 8 of the substrate 2 and the substrate support 100. As will be appreciated by those of skill in the art in view of the present disclosure, the unperforated portion 138 of the concavity 122 axially spaces issue of the etchant 22 issued by the perforations 140 from the backside 8 of the substrate 2 according to the arcuate profile defined by the concavity 122 and diameter of the perforated portion 136 of the concavity 122. In certain examples, the perforated portion 136 of the concavity 122 may have a diameter that is between about 200 millimeters and about 250 millimeters, the unperforated portion 138 of the concavity 122 may have a radial width that is between about 20 millimeters and about 60 millimeters.

Without being bound by a particular theory or mode of operation, it is believed that axially spacing issued of the etchant 22 from the backside 8 of the substrate 2 limits (or eliminates) the tendency of the etchant 22 to generate backside artifacts with the backside 8 (and the potential contamination generation potentially associated with such backside artifacts) without reducing the beneficial effect provided by issue of the etchant 22 into the cavity 39 with respect to the development of backside accretion on the backside 8 of the substrate 2. In this respect ratio of the radial width of the unperforated portion 138 to a diameter of the perforated portion 136 may be between about 1:10 and about 1:1, or between about 3:10 and about 1:1, or between about 5:1 and about 1:1. Applicant has determined that ratios within these ranges allow the etchant 22 to be introduced into the lower chamber 92 (shown in FIG. 3) of the chamber body 62 (shown in FIG. 3) with a mass flow rate to further etch the stem portion 17 (shown in FIG. 4) of the lift pin 78 (shown in FIG. 4) with efficacy sufficient to limit (or eliminate) accretion development, preventing binding of the lift pin 78 during movement through the substrate support 100. As will be appreciated by those of skill in the art in view of the present disclosure, this can improve the reliability of the semiconductor processing system 10, for example, during deposition when employed to deposit relative thick silicon-containing epitaxial layers onto the substrate 2.

In certain examples, the substrate support 100 may define one or more lift pin aperture 142. It is contemplated that the one or more lift pin aperture 142 be configured to slidably receive therethrough a respective lift pin, e.g., the lift pin 78 (shown in FIG. 4), for seating and unseating the substrate 2 shown in FIG. 1) from the substrate support 100. In this respect the one or more lift pin aperture 142 may extend through the thickness 108 of the disc body 102 and couple the lower surface 104 of the disc body 102 with the upper surface 106 of the disc body 102. In the illustrated example the one or more lift pin aperture 142 is defined within the concavity 122. More specifically, the one or more lift pin aperture 142 is defined within the unperforated portion 138 of the concavity 122 such that none of the plurality of perforations 140 radially separate the one or more lift pin aperture 142 from the rim portion 118 of the upper surface 106 of the disc body 102. As will be appreciated by those of skill in the art in view of the present disclosure, limiting the diameter of the perforated portion 136 allows for relatively high mass flow rates of etchant 22 (shown in FIG. 1) to be provided to the lower chamber 92 (shown in FIG. 3) of the chamber body 62 (shown in FIG. 3) while limiting the tendency that the relatively high mass flow rate of the etchant 22 could otherwise have in imparting backside artifacts (and/or damage such as pitting) into the backside 8 (shown in FIG. 6) of the substrate 2 (shown in FIG. 1). In the illustrated example one or more lift pin aperture 142 includes three (3) lift pin apertures. As will also be appreciated by those of skill in the art in view of the present disclose, the substrate support 100 may have fewer or additional lift pin apertures and remain within the scope of the present disclosure.

With continuing reference to FIG. 10, the one or more elongated slot 116 may be defined radially inward of the rim portion 118 of the disc body 102. The one more elongated slot 116 may be defined radially inward of the ledge portion 120 of the disc body 102. The one or more elongated slot 116 may be defined radially outward of the perforated portion 136 of the disc body 102. In the illustrated example the one or more elongated slot 116 is defined radially between the perforated portion 136 of the disc body 102 and the one or more lift pin aperture 142 such that the unperforated portion 138 of the disc body 102 overlays the one or more elongated slot 116, none of the plurality of perforations 140 radially separating the elongated slot 116 from the rim portion 118 of the disc body 102.

In certain examples, the one or more elongated slot 116 may be defined radially between the one or more lift pin aperture 142 and the rotation axis 98. As will be appreciated by those of skill in the art in view of the present disclosure, defining the one or more elongated slot 116 radially between (e.g., radially inward) lifts the radial extent required of the support member 72 (shown in FIG. 3) need have for fixation to the support member 72, limiting size of the support member 72 and simplifying control of temperature of the substrate 2 (shown in FIG. 1) during deposition of the material layer 4 (shown in FIG. 1) onto the top surface 6 (shown in FIG. 1) of the substrate 2 (shown in FIG. 1). In accordance with certain examples, the unperforated portion 138 of the concavity 122 may axially overlay the one or more elongated slot 116. In the illustrated example the one or more elongated slot 116 comprises three (3) elongated slots defined within the lower surface 104 of the disc body 102 and extending radially relative to the rotation axis 98. As will be appreciated by those of skill in the art in view of the present disclosure, the substrate support 100 may have fewer or additional elongated slots and remain within the scope of the present disclosure.

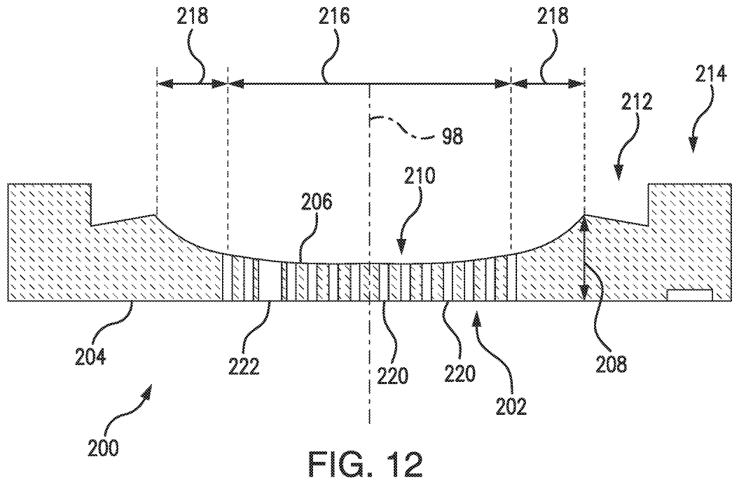

Referring now to FIGS. 12-14, a substrate support 200 is shown. As shown in FIG. 12, the substrate support 200 is similar to the substrate support 100 (shown in FIG. 1) and additionally includes a disc body 202. The disc body 202 is arranged along the rotation axis 98 and has a lower surface 204 and an upper surface 206. The lower surface 204 extends about the rotation axis 98 and is circular in shape. The upper surface 206 is axially offset from the lower surface 204 by a thickness 208 of the disc body 202 and has a concavity 210, a ledge portion 212, and a rim portion 214. The concavity 210 is circular in shape and defines a concave profile intersecting the rotation axis 98 and diametrically spanning the ledge portion 212 of the upper surface 206 of the disc body 202. The ledge portion 212 is located radially outward of the concavity 210, is annular in shape, and extends circumferentially about the concavity 210. The rim portion 214 is located radially outward of the ledge portion 212 of the upper surface 206, is annular in shape, and extends circumferentially about the ledge portion 212 of the upper surface 206 of the disc body 202. It is contemplated that the concavity 210 have a perforated portion 216 and an unperforated portion 218.

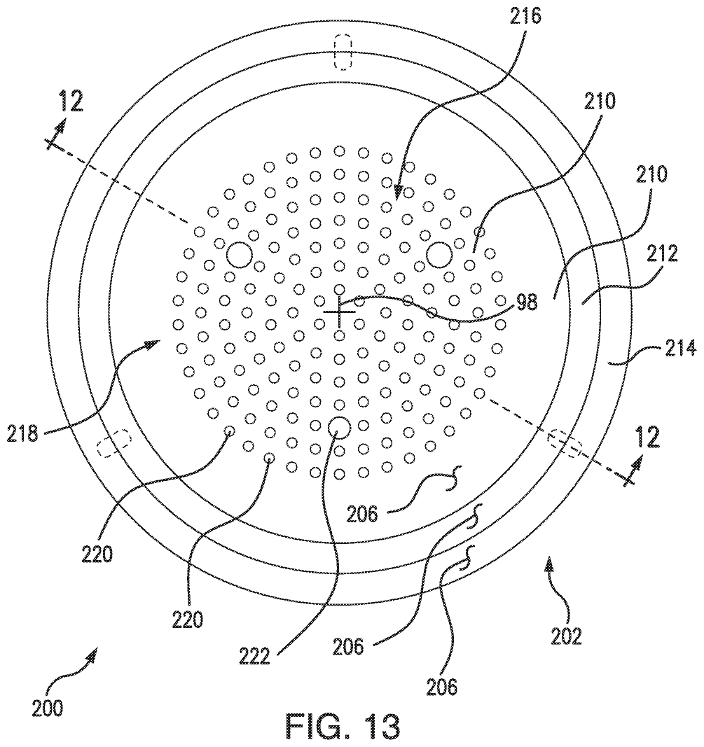

As shown in FIG. 13, the perforated portion 216 of the concavity 210 extends about the rotation axis 98, is circular in shape, and defines a plurality of perforations 220. The plurality of perforations 220 extend through the thickness 208 of the disc body 202 and fluidly couple the lower surface 204 (shown in FIG. 12) of the disc body 202 with the upper surface 206 of the disc body 202. The unperforated portion 218 of the concavity 210 is located radially outward of the perforated portion 216, is annular in shape, and extends circumferentially about perforated portion 216 of the concavity 210. It is contemplated that the perforated portion 216 of the concavity 210 define one or more lift pin aperture 222. The one or more lift pin aperture 222 is configured to slidably receive there a lift pin, e.g., the lift pin 78 (shown in FIG. 6), and in this respect extends through the thickness 208 of the disc body 202 to couple the lower surface 204 to the upper surface 206 of the disc body 202. It is further contemplated that the one or more of the plurality of perforations 220 radially separate the one or more lift pin aperture 222 from the ledge portion 212 of the upper surface 206 of the disc body 202, the one or more lift pin aperture 222 being located radially inward of the unperforated portion 218 of the concavity 210. As will be appreciated by those of skill in the art in view of the present disclosure, locating the one or more lift pin aperture 222 within the perforated portion 216 of the concavity 210 allows etchant issued by through the plurality of perforations 220, e.g., the etchant 22 (shown in FIG. 1), to etch the tip portion 15 (shown in FIG. 6) while the captive in the disc body 202 prior to diffusing, increasing etching (and/or accretion removal) at the tip portion 15 in relation to examples having the one or more lift pin aperture located in the unperforated portion of the concavity 210.

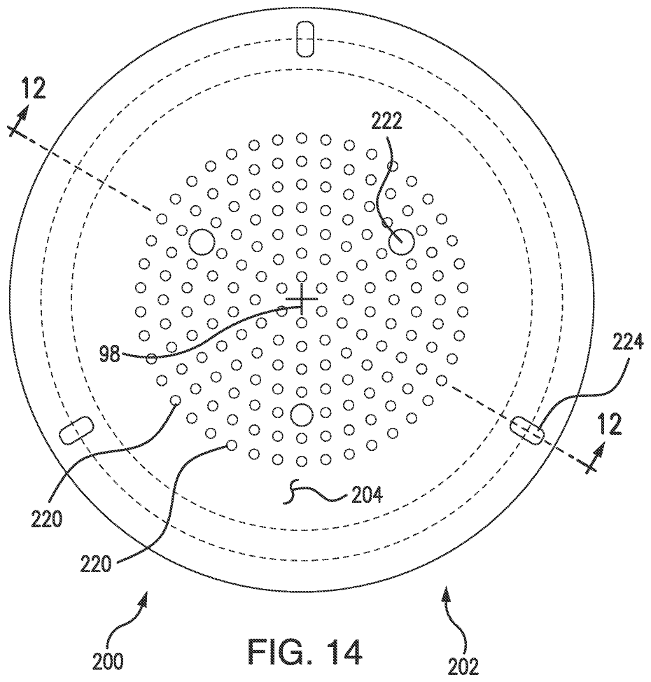

As shown in FIG. 14, the lower surface 204 of the disc body 202 defines there one or more elongated slot 224. In the illustrated example the one or more elongated slot is defined below the rim portion 214 (shown in FIG. 12) of the upper surface 206 (shown in FIG. 12) of the disc body 202. In this respect the one or more elongated slot 224 is defined radially outward of both the concavity 210 (shown in FIG. 12) and the ledge portion 212 (shown in FIG. 12) of the upper surface 206 of the disc body 202, the one or more elongated slot 224 configured to receive therein an axially extending finger of the support member 72 (shown in FIG. 3). As will be appreciated by those of skill in the art in view of the present disclosure, defining the one or more elongated slot 224 below the rim portion 118 radially outward of the ledge portion 212 locates the one or more elongated slot radially outward of the substrate 2, limiting (or eliminating) any thermal variation in the substrate during deposition of the material layer 4 (shown in FIG. 1) that could otherwise be associated with the structural discontinuity associated with the one or more elongated slot 224. In the illustrated example the one or more elongated slot 224 is circumferentially offset from the one or more lift pin aperture 222. As will also be appreciated by those of skill in the art in view of the present disclosure, locating the one or more elongated slot 224 at a position circumferentially offset from the one or more lift pin aperture 222 allows the support member 72 to relatively narrow, limiting shading of the substrate support 200 by the support member 72 and limiting (or eliminating) any heating non-uniformity of the substrate 2 otherwise associated by position of the support member 72 axially between the lower lamp array 68 (shown in FIG. 3) and the lower surface 204 of the disc body 202.

With reference to FIG. 15, the material layer deposition method 300 is shown. As with box 310, the method 300 includes seating a substrate, e.g., the substrate 2 (shown in FIG. 1), on a substrate support, e.g., the substrate support 100 (shown in FIG. 1). The substrate may be seated on the substrate support such that the substrate overlays a concavity, e.g., the concavity 122 (shown in FIG. 9), defined by an upper surface, e.g., the upper surface 106 (shown in FIG. 9), of the substrate support. The substrate may be seated on the substrate support such that the substrate overlays a perforated portion, e.g., the perforated portion 136 (shown in FIG. 9), of the concavity. The substrate may be seated on the substrate support such that substrate overlays an unperforated portion, e.g., the concavity 122 (shown in FIG. 9), of the concavity. The substrate may be support on a ledge portion, e.g., the ledge portion 120 (shown in FIG. 9), of the upper surface of the substrate support. The substrate may be seated on a substrate seat e.g., on the substrate seat 130 (shown in FIG. 1), located on the ledge portion of the substrate support and extending circumferentially about the concavity. The substrate may be peripherally supported on the substrate support, e.g., seated such that a radially outer edge or bevel of the substrate abuts the ledge portion of the substrate support. The substrate may be supported such that a backside of the substrate, e.g., the backside 8 (shown in FIG. 8), abuts the ledge portion of the substrate support, a radially outer peripheral portion of the substrate is cantilevered over the ledge portion of the substrate support radially outward of the substrate seat.

As shown with box 320, a material layer precursor, e.g., the material layer precursor (shown in FIG. 1), may be flowed across the upper surface of the substrate. In certain examples material layer precursor may include a silicon-containing precursor. For example, the silicon-containing precursor may include silane (SiH₄), dichlorosilane (H₂SiCl₂), or trichlorosilane (HCbSi). In accordance with certain examples, the material layer precursor may include germanium. Examples of suitable germanium-containing precursors include germane (GeH₄). It is contemplated that, in certain examples, the material layer precursor may include a dopant. For example, the material layer precursor may include a p-type dopant or an n-type dopant. Examples of suitable dopants include arsine (AsH₃), diborane (B₂H₆), and phosphine (PH₃). It is also contemplated that, in accordance with certain examples, the material layer precursor may include a carrier/purge gas. Examples of suitable carrier/purge gases include hydrogen (H₂), nitrogen (N₂), helium (He), argon (Ar).

As shown with box 330, a material layer, e.g., the material layer 4 (shown in FIG. 1), may be deposited onto the substrate. The material layer may be a silicon-containing layer. The material layer may be an epitaxial layer. The material layer may include an alloy such as germanium (Ge). The material layer include a dopant such arsenic (As), phosphorous (P), and/or boron (B). It is also contemplated that the material layer may be a thick epitaxial silicon layer. In the respect the material layer may have a thickness that is between about 50 microns and about 100 microns, or between about 70 microns and about 100 microns, or even between about 90 microns and 100 microns. It is contemplated that in certain examples, the substrate be heated to and maintained at a predetermined deposition temperature during deposition of the material layer onto the substrate. The predetermined material layer deposition temperature may be between about 500 degrees Celsius and about 1200 degrees Celsius, or between about 700 degrees Celsius and about 1200 degrees Celsius, or even between about 900 degrees Celsius and about 1200 degrees Celsius. It is also contemplated that, in accordance with certain examples, the interior of the chamber body may be maintained at a predetermined material layer deposition temperature during the deposition of the material layer onto the substrate. The material layer deposition temperature may be between about 1 torr and about 760 torr, or between about 20 torr and about 760 torr, or even between about 50 torr and about 760 torr.

As shown with box 340, an etchant, e.g., the etchant 22 (shown in FIG. 1), may be flowed across a lower surface of the substrate support, e.g., the lower surface 104 (shown in FIG. 9), during the deposition of the material layer onto the substrate. The etchant may include a halide such as chlorine or fluorine. The etchant may include chlorine (Cl₂) gas. The etchant may include hydrochloric acid (HCl). The etchant may etch a stem portion of a lift pin dangling from the substrate support, e.g., the stem portion 17 (shown in FIG. 4) of the lift pin 78 (shown in FIG. 4), as shown with box 342, etching an accretion (e.g., the accretion 31 shown in FIG. 7), disposed on the stem portion of the lift pin. The etchant may etch an interior surface of a chamber body housing the substrate support, e.g., an interior surface of chamber body 62 (shown in FIG. 3), etching the interior surface and/or an accretion (e.g., the accretion 33 showing in FIG. 3) disposed on the interior surface of the chamber body. The etchant may etch a portion of the upper surface of the substrate support and/or the backside of the substrate bounding the cavity between the substrate support and the substrate, the etchant etching (and removing) an accretion (e.g., the accretion 37 shown in in FIG. 7) disposed on either (or both) the upper surface of the substrate support and the backside of the substrate.

As shown with box 350, the etchant may be communicated to an upper surface of the substrate support, e.g., the upper surface 106 (shown in FIG. 9), through the substrate support. The etchant may be communicated through a plurality of perforations, e.g., the perforations 140 (shown in FIG. 9), defined by the perforated portion of the concavity and fluidly coupling the lower surface of the substrate support to the upper surface of the substrate support.

As shown with box 360, the etchant may be issued into a cavity defined between the substrate support and the substrate, e.g. the cavity 39 (shown in FIG. 6), using the perforations defined within the perforated portion of the concavity. Issue of the etchant may be limited to only a portion of the concavity. More specifically, issue of the etchant may be limited to a radially inward portion of the concavity. Specifically, no etchant may issue into the cavity radially outward of the perforated portion of the concavity through the unperforated portion of the concavity. As will be appreciated, axial spacing between the substrate and issue of the etchant therefore corresponds to curvature of the arcuate profile of the concavity with radial width of the unperforated portion of the concavity.

As shown with box 370, issue of the etchant into the cavity may be axially spaced apart, e.g., along the rotation axis 98 (shown in FIG. 3), by unperforated portion of the concavity. The axial separation may be selected such that the etchant diffuse into an atmosphere contained within the cavity between the upper surface of the substrate support and the substrate seated on the substrate support. The concentration of the etchant within the atmosphere may be selected according to a ratio of a radial width of the unperforated portion of the concavity and a diameter of the perforated portion of the concavity. In this respect it is contemplated that the ratio of the radial width of the unperforated portion of the concavity to the width (e.g., diameter) of the perforated portion of the concavity may be between about 1:10 and about 1:1, or between about 3:10 and about 1:1, or even between about 5:1 and abut 1:1 to limit concentration of the etchant at the backside of the substrate subsequent to issue into the cavity defined between the substrate support and the substrate.

As shown with box 380, the etchant may etch one of more of the upper surface of the substrate support and/or the backside of the substrate bounding the cavity. Once within the cavity, the etchant may etch either (or both) the upper surface of the substrate support and/or the backside of the substrate during the deposition of the material layer onto the top surface of the substrate. It is contemplated that the etching remove (or prevent development) of accretions on either (or both) the upper surface of the substrate support and the backside of the substrate bounding the cavity between the substrate support and the substrate seated on the substrate support. It is also contemplated that the diffusion of the etchant prior to arrival at the backside of the substrate due to the axial separation provided by the unperforated portion of the concavity be such that concentration of the etchant is insufficient to damage the backside of the substrate, e.g., by pitting the backside at location registered to the perforation and/or by generating a haze on the backside of the substrate. As will be appreciated by those of skill in the art in view of the present disclosure, prevention of such backside damage can limit (or eliminate) the generation of particulate contamination during subsequent handling and/or processing of the substrate.

The terminology used herein is for the purpose of describing particular embodiments only and is not intended to be limiting of the present disclosure. As used herein, the singular forms “a”, “an”, and “the” are intended to include the plural forms as well, unless the context clearly indicates otherwise. It will be further understood that the terms “comprises” and/or “comprising”, when used in this specification, specify the presence of stated features, integers, steps, operations, elements, and/or components, but do not preclude the presence or addition of one or more other features, integers, steps, operations, element components, and/or groups thereof.

The term “about” is intended to include the degree of error associated with measurement of the particular quantity based upon the equipment available at the time of filing the application. For example, “about” can include a range of .+−0.8% or 5%, or 2% of a given value, or variations thereon based on the technology and concepts involved with a particular value or range, and as understood by those of skill in the particular art. Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e., one, two, three, four, etc. The term “a plurality” is understood to include any integer number greater than or equal to two, i.e., two, three, four, five, etc. The term “connection” can include an indirect “connection” and a direct “connection”.

While the present disclosure has been described with reference to an exemplary embodiment or embodiments, it will be understood by those skilled in the art that various changes may be made, and equivalents may be substituted for elements thereof without departing from the scope of the present disclosure. In addition, many modifications may be made to adapt a particular situation or material to the teachings of the present disclosure without departing from the essential scope thereof. Therefore, it is intended that the present disclosure is not limited to the particular embodiment disclosed as the best mode contemplated for carrying out this present disclosure, but that the present disclosure will include all embodiments falling within the scope of the claims.

1. A substrate support, comprising:
a disc body arranged along a rotation axis with an upper surface and a lower surface axially offset by a thickness of the disc body, the upper surface having:
a circular concavity extending about the rotation axis;
an annular ledge portion radially outward of the concavity and extending circumferentially about the concavity;
annular rim portion radially outward of the ledge portion and extending circumferentially about the ledge portion;
wherein the concavity has a circular perforated portion extending about the rotation axis with perforations to etch at least one of the substrate support and a backside of a substrate seated on the substrate support with an etchant communicated through the perforations; and
wherein the concavity has an annular unperforated portion radially outward of the perforated portion and extending circumferentially about the perforated portion to axially space issue of the etchant from backside of the substrate to limit etching of the backside of the substrate by the etchant.

2. The substrate support of claim 1, wherein a ratio of widths of the unperforated portion and the perforated portion is between 1:10 and 1:1, or between 3:10 and 1:1, or between 5:1 and 1:1.

3. The substrate support of claim 1, wherein the plurality of perforations extend through the thickness of the disc body, the plurality of perforations fluidly coupling the lower surface of the disc body to the upper surface of the disc body.

4. The substrate support of claim 1, wherein the concavity defines one or more lift pin aperture extending through the thickness of the disc body, the one or more lift pin aperture coupling the lower surface of the disc body to the upper surface of the disc body.

5. The substrate support of claim 4, wherein the one or more lift pin aperture is defined within the perforated portion of the concavity, wherein at least one of the plurality of perforations separates the one or more lift pin aperture from the unperforated portion of the concavity.

6. The substrate support of claim 4, wherein the one or more lift pin aperture is defined within the unperforated portion of the concavity, wherein none of the plurality of perforations radially separate the one or more lift pin aperture from the ledge portion of the disc body.

7. The substrate support of claim 1, wherein the lower surface of the disc body defines therein one or more elongated slot extending radially relative to the rotation axis.

8. The substrate support of claim 7, wherein the unperforated portion of the concavity axially overlays the one or more elongated slot.

9. The substrate support of claim 7, wherein the rim portion of the upper surface of the disc body overlays the one or more elongated slot.

10. The substrate support of claim 1, wherein the ledge portion of the upper surface defines a substrate seat extending circumferentially about the concavity.

11. The substrate support of claim 10, wherein the ledge portion of the upper surface defines a negative ledge angle radially outward of the substrate, the ledge portion sloping downward toward the lower surface of the disc body radially outward of the substrate seat.

12. The substrate support of claim 10, wherein the ledge portion of the upper surface defines a positive ledge angle radially outward of the substrate, the ledge portion sloping upwards and away from the lower surface of the disc body radially outward of the substrate seat.

13. The substrate support of claim 1, wherein the perforated portion of the concavity has a diameter between about 200 millimeters and about 250 millimeters, wherein the unperforated portion has a radial width between about 20 millimeters and about 60 millimeters.

14. A semiconductor processing system, comprising:
a chamber body with a hollow interior;
a divider with a divider aperture fixed within the interior of the chamber body and separating the interior into an upper chamber and a lower chamber;
a substrate support as recited in claim 1 arranged within the divider aperture and supported for rotation within the interior of the chamber body for rotation about the rotation axis;
wherein the concavity has one or more lift pin aperture extending through the thickness of the disc body, the one or more lift pin aperture fluidly coupling the lower surface of the disc body to the upper surface of the disc body; and
wherein the lower surface of the disc body has one or more elongated slot defined therein and extending radially relative to the rotation axis.

15. The semiconductor processing system of claim 14, wherein the one or more lift pin aperture is defined within the perforated portion of the concavity, wherein at least one of the plurality of perforations separates the one or more lift pin aperture from the unperforated portion of the concavity, wherein the rim portion of the upper surface of the disc body overlays the one or more elongated slot, and wherein the one or more elongated slot is radially aligned with the one or more lift pin aperture.

16. The semiconductor processing system of claim 14, wherein the one or more lift pin aperture is defined within the unperforated portion of the concavity, wherein none of the plurality of perforations radially separate the one or more lift pin aperture from the ledge portion of the upper surface of the disc body, wherein the unperforated portion of the concavity axially overlays the one or more elongated slot, and wherein the one or more elongated slot is circumferentially offset from the one or more lift pin aperture.

17. The semiconductor processing system of claim 14, wherein the ledge portion of the upper surface defines a substrate seat extending circumferentially about concavity, and wherein the ledge portion of the upper surface defines a negative ledge angle radially outward of the substrate seat, the ledge portion sloping downward toward the lower surface of the disc body radially outward of the substrate seat.

18. The semiconductor processing system of claim 14, wherein the ledge portion of the upper surface defines a substrate seat extending circumferentially about concavity, and wherein the ledge portion of the upper surface defines a positive ledge angle radially outward of the substrate seat, the ledge portion sloping upwards and away from the lower surface of the disc body radially outward of the substrate seat.

19. The semiconductor processing system of claim 14, further comprising:
an injection flange connected to the chamber body;
a first precursor source fluidly coupled to the upper chamber of the chamber body by the injection flange and therethrough to the lower chamber by the divider aperture, the first precursor source including a silicon-containing precursor; and
an etchant source fluidly coupled to the lower chamber of the chamber body by the injection flange and therethrough to the upper chamber by the plurality of perforations extending through the thickness of the disc body, the etchant source including hydrochloric acid.

20. A material layer deposition method, the method comprising the steps of:
at a substrate support including a disc body arranged along a rotation axis and having an upper surface and a lower surface axially offset by a thickness of the disc body, the upper surface having a circular concavity extending about the rotation axis, an annular ledge portion radially outward of the concavity and extending circumferentially about the concavity, an annular rim portion radially outward of the ledge portion and extending circumferentially about the ledge portion, the concavity having a circular perforated portion extending about the rotation axis with perforations, the concavity further having an annular unperforated portion radially outward of the perforated portion and extending circumferentially about the perforated portion,
seating the substrate on the substrate support;
flowing a material layer precursor across the substrate;
depositing a material layer onto the substrate using the material layer precursor;
flowing an etchant to the lower surface of the substrate during the step of depositing the material layer onto the substrate;
communicating the etchant to the upper surface of the substrate support through the perforated portion of concavity;
issuing the etchant into a cavity defined between the substrate support and a backside of the substrate using the perforated portion of the concavity and to etching at least one of the substrate support and a backside of a substrate seated on the substrate support; and
axially spacing issue of the etchant from the backside of the substrate using the unperforated portion of the concavity to limit etching of the backside of the substrate by the etchant using the unperforated portion of the concavity.
